(19) United States
(12) Patent Application Publication
(10) Pub. No.: US 2024/0194529 A1
(43) Pub. Date: Jun. 13, 2024

(54) APPARATUS WITH SELF-ALIGNED CONNECTION AND RELATED METHODS

(71) Applicant: Micron Technology, Inc., Boise, ID (US)

(72) Inventors: Shyam Surthi, Boise, ID (US); David H. Wells, Boise, ID (US)

(21) Appl. No.: 18/507,019

(22) Filed: Nov. 10, 2023

Related U.S. Application Data
(60) Provisional application No. 63/431,990, filed on Dec. 12, 2022.

(51) Int. Cl. H01L 21/768; H01L 21/033; H01L 21/32; H10B 69/00

(52) U.S. Cl. CPC H01L 21/76897; H01L 21/0334; H01L 21/32; H01L 21/76805; H10B 69/00

(57) ABSTRACT

Semiconductor devices including self-aligned vertical connectors are disclosed herein. The self-aligned vertical connectors may have upper and lower portions that are concentric or have fixed relative positions across the connectors. The concentric or fixed relative positions may be aligned with a corresponding circuit or a bit line based on forming a conformal depression by depositing a controlled amount of conformal layer that fills wells adjacent to the bit line at a target location of the vertical connector. The vertical connector can be formed using the conformal depression, which may be self-aligned relative to the bit line as a result of filling the wells with the controlled amount of the conformal layer.

### CROSS-REFERENCE TO RELATED APPLICATION(S)

The present application claims priority to U.S. Provisional Patent Application No. 63/431,990, filed Dec. 12, 2022, the disclosure of which is incorporated herein by reference in its entirety.

### TECHNICAL FIELD

The present technology is directed to apparatuses, such as semiconductor devices including memory and processors, and several embodiments are directed to semiconductor devices that include self-aligned connections.

### BACKGROUND

The current trend in semiconductor fabrication is to manufacture smaller and faster devices with a higher density of components for computers, cell phones, pagers, personal digital assistants, and many other products. However, decrease in circuit size can cause increase in manufacturing defects. For example, smaller footprint and increased density can lead to increased shorts or unintended electrical connections.

### BRIEF DESCRIPTION OF THE DRAWINGS

FIG. 1A illustrates a side view of an apparatus in accordance with embodiments of the technology.

FIG. 1B illustrates a schematic cross-sectional view of a portion of the apparatus in accordance with embodiments of the technology.

FIG. 2A-FIG. 2F illustrate a first example manufacturing process.

FIG. 3-FIG. 13 illustrate a second example manufacturing process in accordance with embodiments of the technology.

FIG. 14 is a flow diagram illustrating an example method of manufacturing an apparatus in accordance with an embodiment of the present technology.

FIG. 15 is a schematic view of a system that includes an apparatus configured in accordance with embodiments of the present technology.

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

Several embodiments of semiconductor devices, packages, assemblies, or combinations thereof in accordance with the present technology can include one or more self-aligned connectors. The self-aligned connectors can extend vertically and may have one or more physical characteristics resulting from a self-aligning manufacturing process. For example, the self-aligned connectors can be formed by opening the guide areas (e.g., depressions) around a targeted connection location and then depositing a controlled amount of an oxide in the open area. Given the shape of the guide areas and the controlled amount of the oxide, the deposited oxide can form a convex depression centered over the targeted connection location based on the oxide flowing into the opened guide area. The self-aligned connectors can be filled by depositing or plating an electrically conductive material (e.g., metallic conductors) in the convex depression. Such self-aligning manufacturing process can produce one or more corresponding physical characteristics in the resulting connectors. For example, the self-aligned connectors can consistently have concentric arrangement between outer or upper peripheral portions and inner vertical connector portions.

The self-aligned connectors and the corresponding manufacturing method can provide reduced manufacturing cost, improve yield, and simplify the manufacturing flow. The self-aligning manufacturing process can leverage one mask and a corresponding precision measurement in forming the guide openings and eliminate any additional masks and precision measurements, such as necessary in conventional multi-step masking processes.

### Example Environment and Apparatus

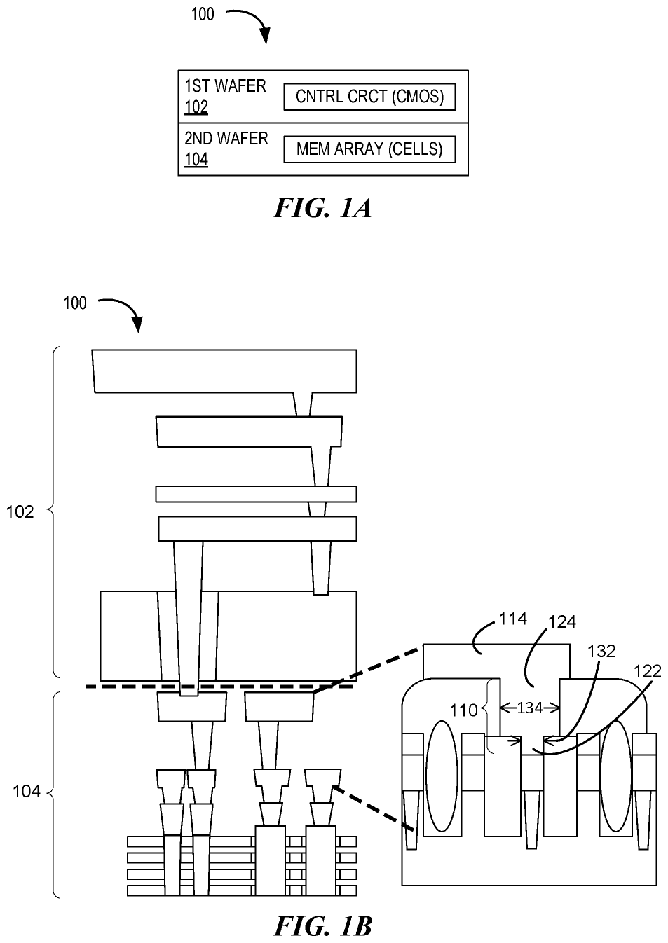

FIG. 1A illustrates a side view of an apparatus 100 (e.g., a semiconductor device, such as a chip, a package, an assembly, or a combination thereof) in accordance with embodiments of the technology. Some examples of the apparatus 100 can include a memory device, such as a random access memory (RAM) (e.g., dynamic RAM (DRAM)), a Flash memory (e.g., a NAND storage device), or the like.

In some embodiments, the apparatus 100 can include a first semiconductor wafer 102 and a second semiconductor wafer 104 stacked or connected to each other, such as for three dimensional integrated circuit (3DI) structures. For example, the apparatus 100 can include a memory device, such as NAND storage chip. One of the wafers can include a storage array (e.g., memory cells) and the other wafer (e.g., a CMOS wafer) can include a control circuit for storing data into and for accessing data from the storage array. The first wafer 102 and the second wafer 104 can have a wafer-to-wafer (W2 W) connection or bond, such as for a face-to-face (F2F) configuration (e.g., a Pads on Array (POA) structure or a Pads on CMOS (POC) structure) or a face-to-back (F2B) configuration (e.g., oxidation to oxidation (Ox-Ox) bond).

FIG. 1B illustrates a schematic cross-sectional view of a portion of the apparatus 100 in accordance with embodiments of the technology. FIG. 1B can illustrate electrical connections between the first wafer 102 and the second wafer. For example, the electrical connections can include a self-aligned connector 110 that extends from an inner or a lower portion of the second wafer 104 (e.g., the memory array) to an interface, such as a landing pad 114. As an illustrative example, the self-aligned connector 110 can include a top bit line connector that extends vertically and provides an electrical connection to a corresponding bit line 116.

The self-aligned connector 110 can have (1) a lower portion 122 that has a first width 132 and is connected to the bit line 116 and (2) an upper portion 124 that has a second width 134 and is connected to the landing pad 114. The lower portion 122 and the upper portion 124 can each have cylindrical shapes that are arranged concentrically. In other words, center portions of the lower portion 122 and the upper portion 124 can directly overlap each other. Moreover, the lower portion 122 can be directly aligned over the corresponding bit line. Details regarding the self-aligned connector 110 and the corresponding manufacturing process are described below.

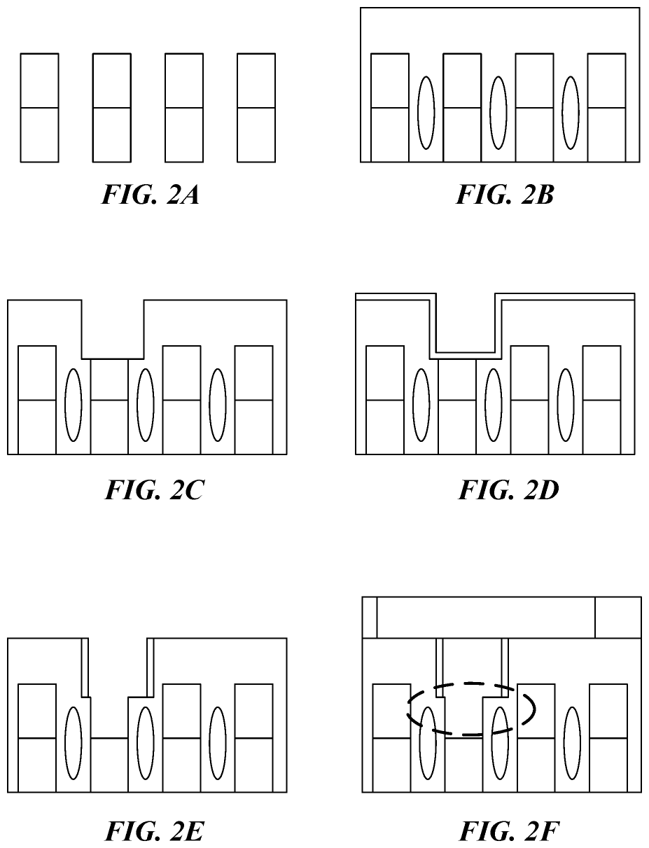

For comparison purposes, FIG. 2A-FIG. 2F illustrate a first example manufacturing process. The first manufacturing process can represent a method of forming vertical connectors.

FIG. 2A can illustrate a manufacturing step for forming bit lines separated from each other by a controlled distance. The bit lines can have a cover layer, such as SiN or CN, thereon.

FIG. 2B can illustrate a manufacturing step for forming an oxide dielectric around or encapsulating the bit lines. The oxide dielectric can be formed with airgaps between each adjacent pair of bit lines.

FIG. 2C can illustrate a manufacturing step for a first etch to pattern and etch away a portion of the oxide dielectric at a target location. Accordingly, the first etch can expose the cover (e.g., nitriride cap) through a resulting opening that is wider (e.g., having a width that is twice or more) than a width of the bit line. Since the first etch is patterned on the oxide dielectric, the resulting opening may or may not be centered over the exposed cover portion. As such, given the difficulties in positioning the opening relative to a targeted portion or location of the bit line, the opening can be wider than the bit line or the corresponding cover portion to ensure an overlap.

FIG. 2D can illustrate a manufacturing step for adding an oxide spacer, such as for protecting the airgaps. For example, the opening resulting from the first etch can overlap one or more airgaps adjacent to the exposed bit line. According, the oxide spacer can be placed to protect the oxide dielectric above the airgaps.

FIG. 2E can illustrate a manufacturing step for a second etch to selectively remove the cover (e.g., nitriride cap) over the targeted location of the bit line. Accordingly, the second etch can expose the bit line at the targeted location.

FIG. 2F can illustrate a manufacturing step for forming a vertical contact (e.g., a bit line contact) and a corresponding metal pad. For example, the vertical contact can be formed by depositing a conductive material (e.g., a conductive metal, such as Cu) in the opening. The resulting vertical contact can have a lower portion and an upper portion that may be offset or non-concentric relative to each other. Moreover, the relative arrangement of the upper and lower portions may be different across multiple vertical connectors within one device.

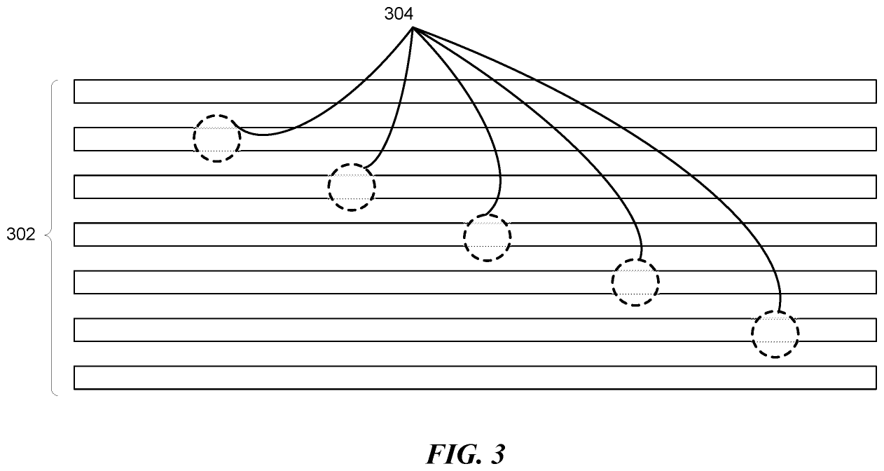

FIG. 3-FIG. 13 illustrate a second example manufacturing process (e.g., a self-aligning manufacturing process) in accordance with embodiments of the technology. FIG. 3-FIG. 13 can illustrate one or more manufacturing steps used to manufacture or form the self-aligned connector 110 (e.g., bit line connector or other vertically extending electrically connectors).

FIG. 3 can illustrate a top view of a set of bit lines 302 in the memory array. FIG. 3 can further correspond to a manufacturing step for identifying target locations 304 for the bit lines 302. Each of the bit lines 302 can have a corresponding one of the target locations 304 that represent to a planned location for the vertical connection or the self-aligned connector 110. The target locations 304 can be offset from each other along a direction parallel to the lengths of the bit lines 302.

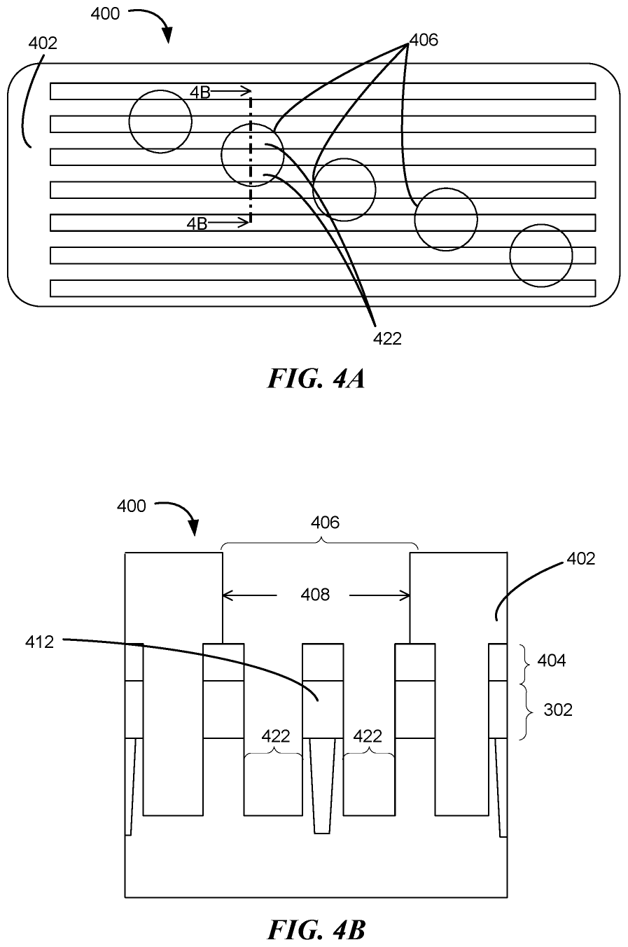

FIG. 4A can illustrate a schematic top view of a structure 400, FIG. 4B can illustrate a cross-sectional view of the structure 400 taken along a line 4B-4B. Referring to FIG. 4A and FIG. 4B together, the structure 400 can include the bit lines 302 encapsulated by a patterning layer 402 (e.g., a resist, such as photo resist, such as multilayer resist (MLR)). The structure 400 can have a cover layer 404, such as SiN or CN, directly over and contacting each of the bit lines 302.

FIG. 4A and FIG. 4B can correspond to a manufacturing step for forming mask openings 406 in the patterning layer 402 at the target locations 304 of FIG. 3. The patterning layer 402 can have a first etch-related property. According to the first etch-related property, the mask openings 406 can be formed in the patterning layer 402.

The mask openings 406 can have an oval, a circular, or a rectangular footprint and expose the cover layers 404, the corresponding portions of the bit lines 302, or both. Each of the mask openings 406 can fully expose a targeted bit line 412 associated with the corresponding target location 304 and the cover layer 404 thereon. The mask openings 406 can further have an opening width 408 that sufficiently exposes areas between the targeted bit line 412 and adjacent bit lines 414. Accordingly, the manufacturing step illustrated for FIG. 4A and FIG.B can include forming or exposing wells 422 (e.g., depressions extending below the targeted bit line 412, such as into the supporting layer underneath) between the targeted bit line 412 and the adjacent bit lines 414. The mask openings 406 may laterally extend beyond the wells 422 and expose portions of the adjacent bit lines 414.

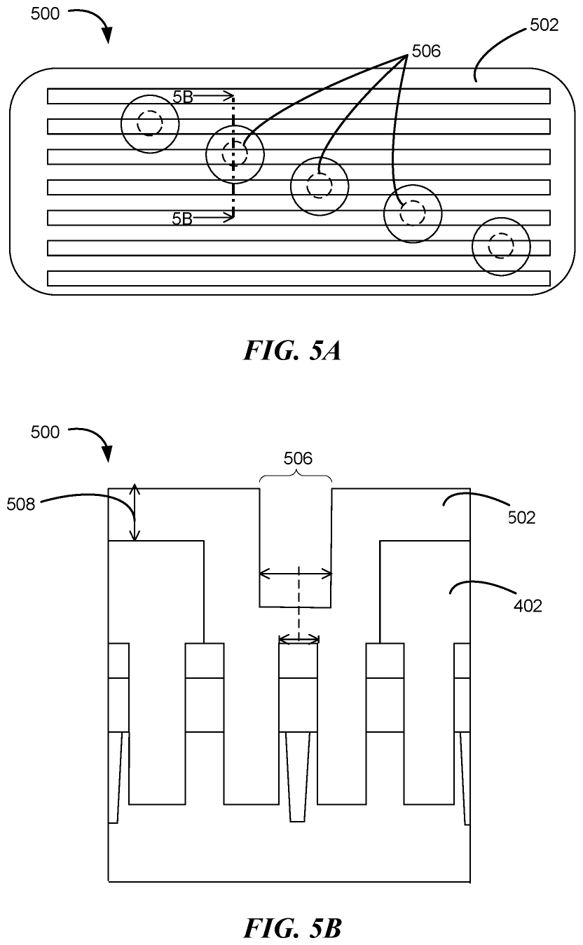

FIG. 5A can illustrate a schematic top view of a structure 500, FIG. 5B can illustrate a cross-sectional view of the structure 500 taken along a line 5B-5B. Referring to FIG. 5A and FIG. 5B together, the structure 500 can include a conformal layer 502 (e.g., an oxidation spacer layer) deposited over the structure 400 of FIG. 4A. For example, FIG. 5A and FIG. 5B can correspond to a manufacturing step for depositing conformal oxide material over the structure 400. The deposited material can be different from the patterning layer 402. For example, the deposited material and the patterning layer 402 can have different removal or etching mechanisms.

The manufacturing step can include controlling an amount of the deposited conformal oxide, such as according to a shape or an opening width 408 of FIG. 4B of the mask openings 406 of FIG. 4A, one or more dimensions of the wells 422 of FIG. 4B, or a combination thereof. In some embodiments, the deposited amount of conformal oxide can be less than a combined volume of the wells 422 and the mask openings 406. In other words, the deposited amount of the conformal oxide can correspond to a thickness 508 for the conformal layer 502. The thickness 508 (e.g., 20 nm) can be less than the opening width 408 (e.g., 40 nm-100 nm) of the mask openings 406, such as by a factor of 2-5 or greater.

Based on the controlled deposit, the conformal layer 502 can have conformal depressions 506 that overlap and coincide with the target locations 304 of FIG. 3 and the corresponding portions or locations of the targeted bit lines 412 of FIG. 4B. The conformal depressions 506 can be concentrically arranged with the target locations 304 based on the conformal layer 502 filling and occupying the wells 422. The conformal depressions 506 can be formed based on the controlled amounts of the conformal oxide filling the wells 422, thereby having less volume above the target bit lines 412 and within the mask openings 406. For example, the controlled amount of the conformal layer 502 can correspond to a targeted thickness (e.g., 20 nm) thereof that is smaller than a dimension (e.g., 80 nm width) of the mask opening 406. Since the wells 422 effectively define opposing peripheral edges of the target bit lines 412, the conformal oxide can fill the surrounding wells 422 at relatively equal rates.

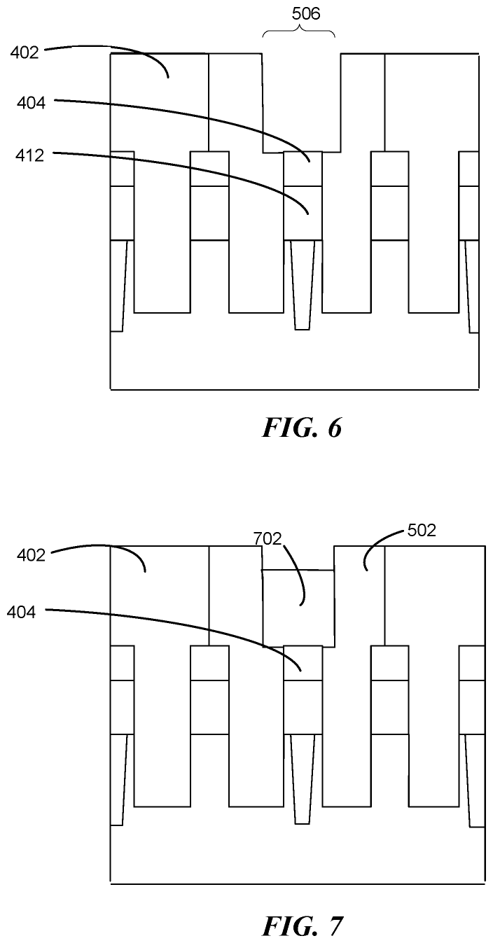

FIG. 6 can illustrate a cross-sectional view of the structure 500 following an etch to remove the conformal layer 502 of FIG. 5B from the conformal depressions 506. In other words, FIG. 6 can correspond to a manufacturing step to deepen the conformal depressions 506 and expose the cover layer 404 or at least a top portion thereof within the conformal depressions 506. The conformal depressions 506 can be deepened such that the bottom portion thereof is coincident with or is below a top portion of the cover layer 404, a top portion of the target bit line 412, or both. Accordingly, the cover layer 404 for the targeted bit line 412 can be exposed through the conformal depressions 506 based on the manufacturing step illustrated in FIG. 6. In some embodiments, the manufacturing step can additionally expose top portions of the patterning layer 402 surrounding the conformal depressions 506.

Based on the manufacturing steps, including filling the surrounding wells 422 at relatively equal rates, the conformal depression 506 can be self-aligned with the target bit lines 412, the conformal layer 502, or both remaining at the target location 304. In other words, the center portion of the conformal depressions 506 can overlap the middle portion (e.g., center) of the target bit lines 412, the remaining conformal layer 502, or both.

FIG. 7 can illustrate a cross-sectional view of the structure 500 with a sacrificial plug 702 filling or occupying the deepened conformal depressions 506 of FIG. 6 and directly contacting the cover layer 404 therein. In other words, FIG. 7 can correspond to a manufacturing step to deposit or grow the sacrificial plug 702 in each of the deepened conformal depressions 506. The sacrificial plug 702 can be formed using material having an etch or a removal mechanism different from that of the conformal layer 502, the patterning layer 402, the cover layer 404, or a combination thereof. For example, the sacrificial plug 702 can include material (e.g., TiO) having relatively lower deposit temperature in comparison to processing temperature of other material, such as the baking temperature of the patterning layer 402. In some embodiments, the sacrificial plug 702 can include metallic material having a melting point below 90° C. (e.g., 75° C. or within a threshold range thereof for TiO). In comparison, for example, the patterning layer 402 (e.g., MLR) can associated with processing temperatures of 250° C.-350° C. Moreover, the sacrificial plug 702 can include material or be associated with depositing process that does not etch, damage, or otherwise deform the shape of the patterning layer 402.

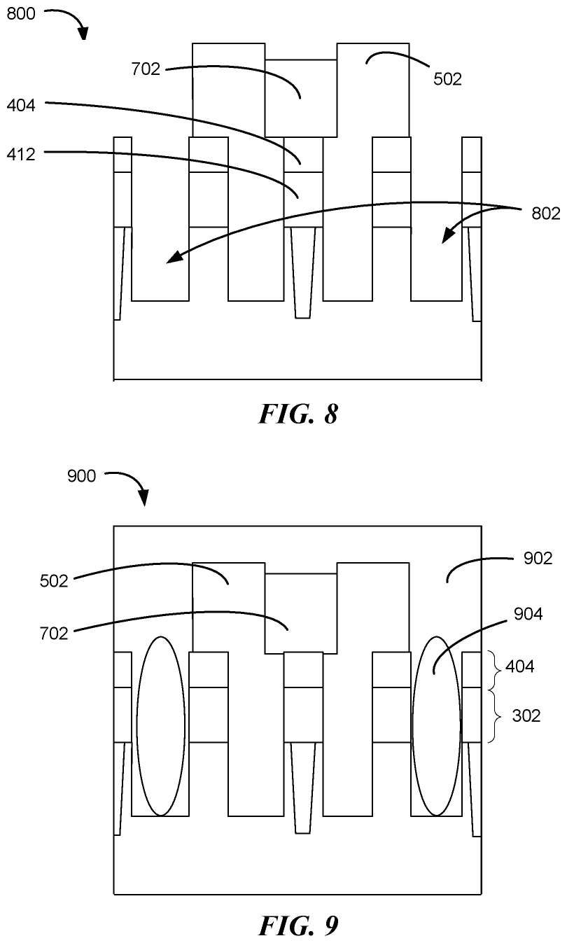

FIG. 8 can illustrate a cross-sectional view of a structure 800 that corresponds to the structure 500 of FIG. 5B. The structure 800 can correspond to the structure 500 remaining after deepening the conformal depressions 506 as illustrated in FIG. 6, forming the sacrificial plug 702 as illustrated in FIG. 7, and subsequently removing the patterning layer 402 of FIG. 7, portions of the conformal layer 502, or both outside of the target locations 304 of FIG. 3. Accordingly, the structure 800 can include the sacrificial plug 702 over the cover layer 404 and the target bit line 412 at the target locations 304. The structure 800 can include portions of the conformal layer 502 remaining at or surrounding the target locations 304. The remaining portions of the conformal layer 502 can correspond to a plug that fills the wells 422 of FIG. 4B. Additionally or alternatively, the corresponding plug can surround lateral or peripheral portions of the sacrificial plug 702, the cover layer 404 or the bit line 412 at the target locations 304, or a combination thereof. The remaining portions of the conformal layer 502 or the conformal plug can cover the bit lines adjacent to the target bit line 412, expose separation spaces 802 opposite the wells 422 across the adjacent bit lines, or both.

FIG. 9 can illustrate a cross-sectional view of a structure 900 that corresponds to the structure 800 of FIG. 8. For example, the structure 900 can correspond to the structure 800 having a dielectric layer 902 (e.g., oxide dielectric) covering the structure 800. In other words, the dielectric layer 902 can be over and cover the sacrificial plug 702, the cover layer 404, the bit lines 302, the remaining portions of the conformal layer 502, or a combination thereof. The dielectric layer 902 can enclose or define airgaps 904 in the separation spaces 802.

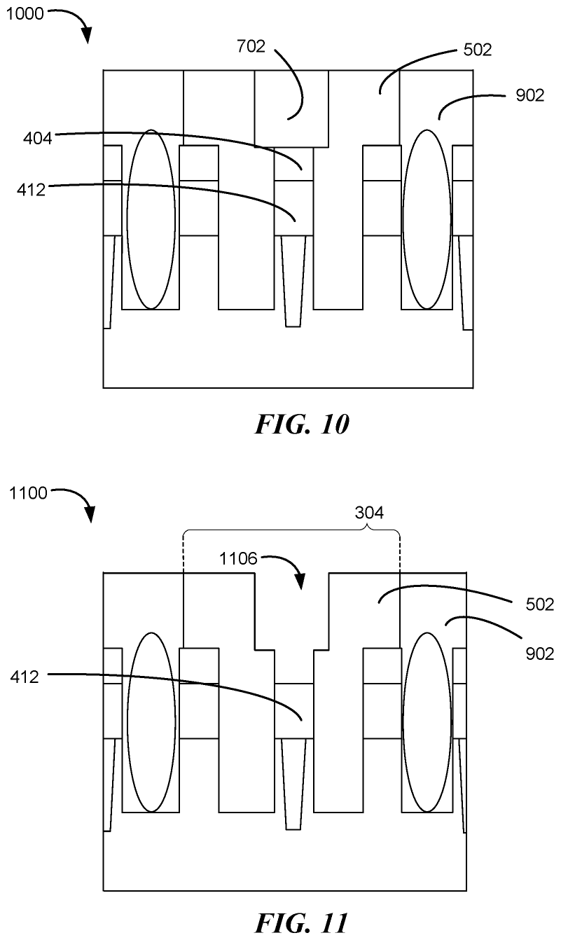

FIG. 10 can illustrate a cross-sectional view of a structure 1000 that corresponds to the structure 900 of FIG. 9. For example, the structure 1000 can correspond a manufacturing step for planarizing or removing a top portion of to the structure 900. Accordingly, the structure 1000 can have the sacrificial plug 702 (e.g., a top portion thereof) exposed. The sacrificial plug 702 can remain over and covering the cover layer 404 and the targeted bit line 412.

In some embodiments, a top portion of the structure 1000 can have a planar top surface. In other words, the top surface of the sacrificial plug can be planar with top surface(s) of the conformal layer 502, the dielectric layer 902, or both.

FIG. 11 can illustrate a cross-sectional view of a structure 1100 that corresponds to the structure 1000 of FIG. 10. For example, the structure 1100 can correspond a manufacturing step for etching away or otherwise removing the sacrificial plug 702 of FIG. 10 and the cover layer 404 of FIG. 10. The manufacturing step can leverage the etching mechanism(s) unique to the sacrificial plug 702, the cover layer 404, or both to the corresponding removal. The leveraged etching mechanism(s) can be different from that of the conformal layer 502, the dielectric layer 902, or both.

Accordingly, the structure 1100 can have a contact opening 1106 that exposes the targeted bit line 412 at the target location 304. The contact opening 1106 can have a shape that is defined by the conformal layer 502, the dielectric layer 902, or both. The shape of the contact opening 1106 can match or correspond to the sacrificial plug 702 and the cover layer 404. For example, the contact opening 1106 can have a lower portion having a narrower width in comparison to a wider upper portion. The lower portion and the upper portion can have center portions directly overlapping. In other words, the lower portion and the upper portions can be concentrically arranged.

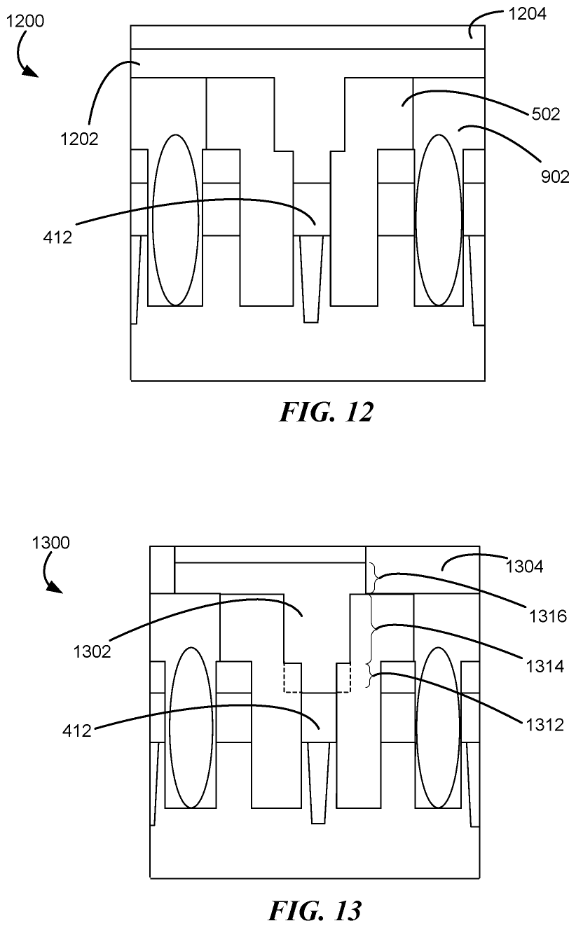

FIG. 12 can illustrate a cross-sectional view of a structure 1200 that corresponds to the structure 1100 of FIG. 11. For example, the structure 1200 can correspond a manufacturing step for forming a conductive layer 1202, an oxidized cover layer 1204, or both. In some embodiments, the manufacturing step can include a metallization process for depositing electrically conductive material, such as copper. Based on the manufacturing step, the conductive layer 1202 can directly contact the targeted bit line 412 and fill and occupy the contact opening 1106 of FIG. 11. The conductive layer 1202 can extend over and cover the conformal layer 502, the dielectric layer 902, or both. In other words, the conductive layer 1202 can extend laterally beyond the peripheral edges of the contact opening 1106 and directly contact top portions (e.g., top surfaces) of the conformal layer 502, the dielectric layer 902, or both. The oxidized cover layer 1204 can be formed or deposited on or over the conductive layer 1202.

FIG. 13 can illustrate a cross-sectional view of a structure 1300 that corresponds to the structure 1200 of FIG. 12. For example, the structure 1300 can correspond a manufacturing step for forming a vertical connector 1302, a set of oxide fills 1304, or both. In some embodiments, the manufacturing step can include etching away portions of the conductive layer 1202 of FIG. 12, the oxidized cover layer 1204 of FIG. 12, or both to form the vertical connector 1302 (e.g., the remaining portion(s) of the conductive layer 1202, the oxidized cover layer 1204, or both). Each of the formed vertical connector 1302 can directly contact the targeted bit line 412 and extend upward through the contact opening 1106 of FIG. 11 and over the top portions of the conformal layer 502, the dielectric layer 902, or both. As a result of the preceding manufacturing steps (e.g., filling the surrounding wells 422 with controlled amount of deposit as described above for the structure 500 of FIG. 5B), the vertical connector 1302 or one or more portions thereof can be aligned with the conformal plug (e.g., the remaining portions of the conformal layer 502 of FIG. 12), the target bit line 412, or both.

The vertical connector 1302 can include a lower portion 1312 and an upper portion 1314 that are integral with each other. The vertical connector 1302 can further be integral with a landing pad 1316. The lower portion 1312 can directly contact the targeted bit line 412 and fill the portion of the contact opening 1106 previously occupied by the cover layer 404 of FIG. 10. Accordingly, the lower portion 1312 can have lateral portions or dimensions that are similar to or match the cover layer 404.

The upper portion 1314 can be above the lower portion 1312 and fill the portion of the contact opening 1106 previously occupied by the sacrificial plug 702 of FIG. 7. Accordingly, the upper portion 1314 can have lateral portions or dimensions that are similar to or match the sacrificial plug 702. The lower portion 1312 and the upper portion 1314 can be concentric, such as having middle portions of the lower portion 1312 and the upper portion 1314 directly on top of each other (e.g., aligned along a vertical line).

In some embodiments, the vertical connector can have a singular body (illustrated using dashed extension lines) with substantially uniform lateral dimensions or linear sidewalls instead of the upper and lower portions. For example, the cover layer 404 may not be utilized or removed before deepening the conformal depressions 506 as illustrated in FIG. 6. Also, the deepened conformal depressions 506 can extend below the cover layer 404 or down to a top portion of the target bit line 412. As a result, the contact opening 1106 of FIG. 11 can have a cylindrical shape with continuously linear sidewalls or consistent lateral dimension(s) down to the top portion of the target bit line 412. The vertical connector formed within the contact opening 1106 can have the corresponding shape and without the narrower lower portion 1312.

The landing pad 1316 can be above the upper portions of the conformal layer 502, the dielectric layer 902, or both. The landing pad 1316 can extend laterally past one or more lateral edges of the contact opening 1106. Accordingly, the landing pad 1316 can overlap the conformal layer 502, the dielectric layer 902, or both. The landing pad 1316 can be configured to provide electrical contact or connection with another circuit, such as the first semiconductor wafer 102 of FIG. 1A.

The manufacturing step can further include forming a redistribution layer (RDL) for providing electrical connections to or from the vertical connector 1302, the landing pad 1316, or both at other locations. In other words, the manufacturing step can include forming metal or other conductive connections that extend along one or more lateral directions from the vertical connector 1302.

In addition to forming the vertical connector 1302, landing pad 1316, the RDL, or a combination thereof the manufacturing step can include depositing the oxide fills 1304 adjacent to or between the vertical connector 1302, the RDL, or both. After forming or depositing the oxide fills 1304, the structure can be planarized. Accordingly, top portions of the vertical connector 1302, the landing pad 1316, the oxidized cover layer 1204, the oxide fills 1304, or a combination thereof can form a planar surface.

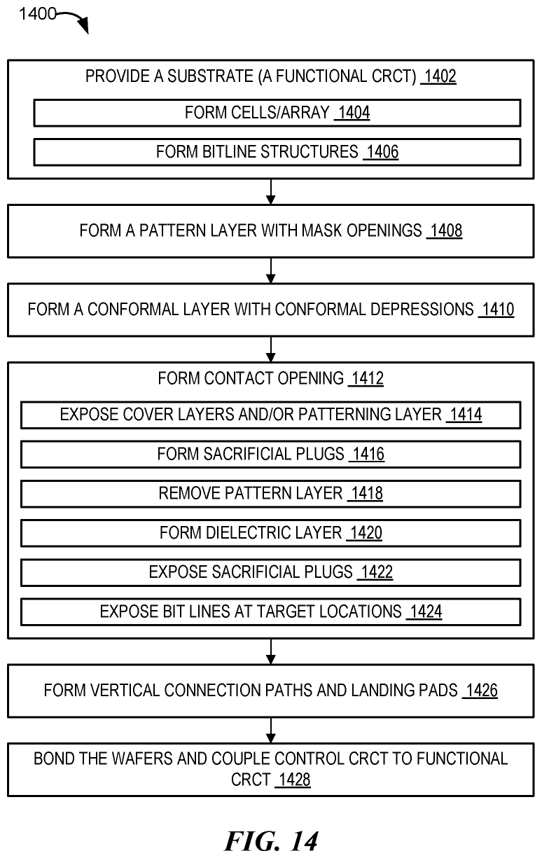

FIG. 14 is a flow diagram illustrating an example method 1400 of manufacturing an apparatus (e.g., the apparatus 100 of FIG. 1A or one or more portions thereof, such as the second wafer 104 of FIG. 1A, the landing pad 1316 of FIG. 13, the corresponding vertical connector, or the like) in accordance with an embodiment of the present technology. The method 1400 can include forming the landing pad 1316, the corresponding vertical connector, or both.

At block 1402, the method 1400 can include providing a substrate, such as the second wafer 104 of FIG. 1A including a functional circuit. For example, the provided substrate can correspond to the processed semiconductor wafer depicted in FIG. 3 having the bit lines 302 of FIG. 3 over the memory cells.

In some embodiments, providing the substrate can include forming or processing the semiconductor wafer. For example, the method 1400 can include forming the memory cells or the memory array as illustrated at block 1404. The memory cells can be formed using an array of transistors or other types of data storage circuits. At block 1406, the method 1400 can include forming bit line structures. For example, the bit lines 302 can be formed extending linearly parallel to each other along a lateral direction. The bit lines 302 can be on raised substrate or dielectric material. The bit lines 302 can be separated by the separation spaces 802 or trenches that extend parallel to the bit lines 302 along a lateral direction and below the bit lines 302 along a vertical direction. Moreover, the bit lines 302 can be covered by the cover layer 404.

At block 1408, the method 1400 can include forming a patterning layer (e.g., the patterning layer 402 of FIG. 4A) with mask openings (e.g., the mask openings 406 of FIG. 4A). Forming the patterning layer can correspond to the processing step illustrated in one or more of FIG. 3, FIG. 4A, and FIG. 4B.

The patterning layer can be formed based on depositing the patterning layer 402 over the bit lines 302 and the cover layer 404. The patterning layer 402 can fill the separation spaces 802 of FIG. 8. Forming the patterning layer can include forming the mask openings 406 at the target locations 304 of FIG. 3, such as by removing the patterning layer 402 or blocking deposition of the patterning layer 402 at the target locations 304. The mask openings 406 can expose the cover layer 404 for the bit line corresponding to the target location. The mask openings 406 can further expose the separation spaces 802 surrounding the target bit line at the target location. The mask openings 406 can be formed having the opening width 408 of FIG. 4B.

At block 1410, the method 1400 can include forming a conformal layer (e.g., the conformal layer 502 of FIG. 5A) with conformal depressions (e.g., the conformal depressions 506 of FIG. 5A). Forming the conformal layer can correspond to the processing step illustrated in FIG. 5A and FIG. 5B.

The conformal layer can be formed by depositing a controlled amount of the corresponding material (e.g., conformal oxide) over the patterning layer 402 and within the mask openings 406. The controlled amount can correspond to the targeted thickness 508 of FIG. 5B for the conformal layer. In some embodiments, the deposited conformal layer can have the targeted thickness 508 (e.g., 20 nm) that is less than the opening width 408 (e.g., 80 nm), such as by a factor of 2.0-6.0.

The exposed portions of the separation spaces 802 surrounding the bit lines at the target locations can function as the wells 422 of FIG. 4B for the deposited material. Accordingly, the deposited material can fill the wells 422, thereby forming a lesser thickness (e.g., thinner than the targeted thickness 508) of the conformal layer 502 over the center portion of the exposed cover layer 404, the targeted bit line 412, or both. The lesser thicknesses can correspond to the conformal depressions 506. The conformal depressions 506 can be directly over a portion (e.g., a center portion) of the corresponding target bit line within each of the mask opening. Also, the conformal depressions 506 can be concentrically arranged with the mask opening, the portion of the corresponding target bit line, or both. The conformal depressions 506 and the relative location or arrangement thereof can correspond to a mold or a guide for forming a portion (e.g., the upper portion) of the self-aligned vertical connector.

At block 1412, the method 1400 can include forming contact openings (e.g., instances of the contact opening 1106). The contact openings can each be a mold or a guide for forming the self-aligned vertical connector. The contact openings can be formed using the conformal depressions 506.

At block 1414, the method 1400 can include exposing portions of the cover layers 404, the patterning layer 402, or both as illustrated in FIG. 6. For example, the cover layers 404 can be exposed at each of the target locations by removing the conformal layer 502 from a bottom portion of each corresponding conformal depression 506. Similarly, the patterning layer 402 can be exposed by removing portions of the conformal layer 502 that are directly over the patterning layer 402, such as outside of the target locations. Portions of the conformal layer 502 can remain within the target locations.

At block 1416, the method 1400 can include forming the sacrificial plugs 702 such as illustrated in FIG. 7. As described above, the sacrificial plugs 702 can be formed directly on the cover layer 404 exposed within each of the conformal depressions 506. The sacrificial plugs 702 can be formed by depositing or growing a material (e.g., TiO) having a removal characteristic different than the conformal layer 502, the patterning layer 402, the cover layer 404, or a combination thereof. For example, the sacrificial plugs 702 can be formed by depositing a metallic material having a processing temperature (e.g., depositing temperature) lower than 90° C.

At block 1418, the method 1400 can include removing the patterning layer 402 of FIG. 7. The removal of the patterning layer 402 can correspond to FIG. 8. The patterning layer 402 can be removed according to the removal characteristic thereof. For example, the patterning layer 402 can be removed using heat, light, chemical, mechanical, or a combination of mechanisms thereof. Accordingly, the separation spaces 802 outside of the target locations and that were previously occupied by the patterning layer 402 can become exposed. The wells 422 within the target locations can remain filled by the conformal layer 502.

At block 1420, the method 1400 can include forming the dielectric layer 902 as illustrated in FIG. 9. The dielectric layer 902 can be formed by depositing a corresponding material (e.g., oxide dielectric material) over and encapsulating the bit lines 302, the sacrificial plugs 702, the conformal layer 502, or a combination thereof. The dielectric layer 902 can further be formed defining and encapsulating the airgaps 904 in the exposed portions of the separation spaces 802.

At block 1422, the method 1400 can include exposing the sacrificial plugs 702. The exposure of the sacrificial plugs 702 can correspond to FIG. 10. For example, a portion of the dielectric layer 902 can be removed, such as via a planarization process, to expose the sacrificial plugs 702.

At block 1424, the method 1400 can include exposing bit lines at target locations. The exposure of the bit lines can correspond to FIG. 11. For example, the sacrificial plugs 702 of FIG. 10 the cover layer 404 of FIG. 10, or both can be removed or etched away according to the corresponding removal characteristics. Accordingly, the removal process can open the contact opening 1106. The upper portion of the contact opening 1106 can correspond to the sacrificial plug 702 and function as a guide or a mold for the upper portion of the vertical connector. The lower portion of the contact opening 1106 can correspond to the cover layer 404 and function as a guide or a mold for the lower portion of the vertical connector.

At block 1426, the method 1400 can include forming vertical connection paths (e.g., instances of the vertical connector 1302 of FIG. 13) and landing pads (the landing pad 1316 of FIG. 13). Formation of the vertical connection paths can correspond to the formation or depositing illustrated in FIG. 12 (e.g., a single metallization process) and a shaping process illustrated in FIG. 13. The vertical connection paths can be formed based on depositing or growing conductive material (e.g., a metallic material, such as copper) directly on or over the bit line exposed at the target location through the contact openings 1106. Accordingly, the vertical connection paths can be configured to provide a conductive path to the target bit line.

At block 1428, the method 1400 can include bonding the wafers together, thereby coupling a control circuit (e.g., the CMOS control circuit) to the functional circuit. For example, the first semiconductor wafer 102 can be bonded over the second semiconductor wafer 104, such as using W2 W, F2F, or F2B bonding techniques. The control circuits in the first wafer 102 can be electrically coupled to the landing pads and the corresponding bit lines.

The self-aligned vertical connectors and the corresponding manufacturing processes described above can provide the vertical connection across the wafers that reduce manufacturing cost and complexities. For example, the self-aligning aspect can reduce one or more precision locating steps, one or more masking steps, or both in comparison to conventional manufacturing processes. The above-described manufacturing method can leverage the precision alignment for forming the conformal plug (such as for locating the mask openings 406 of FIG. 4B relative to the target bit line 412 of FIG. 4B) to subsequently form and align the vertical connector. As such, the above-described manufacturing method can eliminate the precision alignment that may otherwise be necessary in forming the vertical connector in conventional manufacturing methods. Moreover, the self-aligned vertical connectors can provide improved failure rates and improved yield by preventing or reducing shorts between adjacent bit lines. Further, the self-aligned vertical connectors and the landing pads can be formed using a single metallization step, thereby providing reduced manufacturing costs and complexities. The subtractive processing flow can further allow for routing and RDL capabilities for design flexibility (via, e.g., top metal layer).

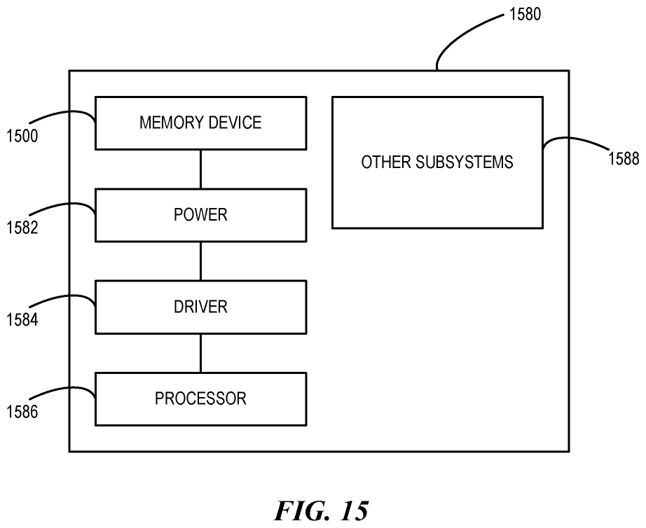

FIG. 15 is a schematic view of a system that includes an apparatus in accordance with embodiments of the present technology. Any one of the semiconductor devices described above with reference to FIGS. 1A-14 can be incorporated into any of a myriad of larger or more complex systems, a representative example of which is system 1590 shown schematically in FIG. 15. The system 1590 can include a semiconductor device 1500 (“device 1500”) (e.g., a semiconductor device, package, assembly, etc.), a power source 1592, a driver 1594, a processor 1596, other subsystems or components 1598. The device 1500 can include features generally similar to those devices described above. The resulting system 1590 can perform any of a wide variety of functions, such as memory storage, data processing, or other suitable functions. Accordingly, representative systems 1590 can include, without limitation, hand-held devices (e.g., mobile phones, tablets, digital readers, and digital audio players), computers, and appliances. Components of the system 1590 may be housed in a single unit or distributed over multiple, interconnected units (e.g., through a communications network). The components of the system 1590 can also include remote devices and any of a wide variety of computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising.” “including.” and “having” are used throughout to mean including at least the recited feature(s) such that any greater number of the same feature and/or additional types of other features are not precluded. Reference herein to “one embodiment,” “an embodiment.” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

What is claimed is:

1. A method of manufacturing a semiconductor device, the method comprising:
providing a semiconductor substrate configured for housing a data storage cells, wherein the provided semiconductor substrate includes (1) bit lines extending linearly and parallel to each other, (2) a cover layer over each of the bit lines, and (3) trenches separating adjacent pairs of the bit lines and extending below the bit lines;
depositing a patterning layer over the target bit line, wherein the patterning layer has a mask opening for the target bit line at a target location, the mask opening exposing (1) the cover layer for the corresponding target bit line and (2) portions of the trenches surrounding the target bit line at the target location;
depositing a controlled amount of a conformal layer over the patterning layer and within the mask opening, wherein depositing the controlled amount of the conformal layer includes forming a conformal depression that is (1) directly over a portion of the corresponding target bit line within the mask opening and (2) concentrically arranged with the mask opening, the portion of the corresponding target bit line, or both;
forming a contact opening at the target location using the conformal depression, wherein forming the contact opening includes removing the cover layer to expose the target bit line at the corresponding target location; and
forming a vertical connector and a landing pad at the target location based on filling the contact opening with electrically conductive material, wherein the vertical contact is configured to provide a conductive path to the target bit line and includes an upper portion and a lower portion that are concentrically arranged.

2. The method of claim 1, wherein depositing the controlled amount of the conformal layer to form the conformal depression and forming the vertical connector based on filling the contact opening comprise forming the vertical connector having the upper and lower portions that are self-aligned according to the concentric arrangement of the mask opening, a portion of the cover layer, the portion of the target bit line, or a combination thereof.

3. The method of claim 2, wherein:
the mask opening has an opening width; and
the controlled amount of the conformal layer corresponds to a thickness of the conformal layer, wherein the thickness is less than the opening width.

4. The method of claim 3, wherein the thickness of the conformal layer is less than the opening width of the mask opening by a factor of 3-5.

5. The method of claim 3, wherein:
the exposed portions of the trenches surrounding the target bit line at the target location function as wells for the conformal layer; and
the self-alignment of the upper and lower portions corresponds to the concentric arrangement between two or more of the mask opening, the cover layer, and the portion of the target bit line resulting from filling the wells and forming a reduced thickness of the conformal layer directly over a center portion of the target bit line within the target location, wherein the reduced thickness corresponds to the conformal depression.

6. The method of claim 1, wherein forming the contact opening includes:
exposing the cover layer at the target location by removing the conformal layer at a bottom portion of the conformal depression;
forming a sacrificial plug directly on the cover layer and within the conformal depression; and
forming the contact opening based on removing the sacrificial plug and the cover layer after forming one or more oxide structures around the sacrificial plug, wherein a portion previously occupied by the sacrificial plug corresponds to the upper portion of the vertical connector and a portion previously occupied by the cover layer corresponds to the lower portion of the vertical connector.

7. The method of claim 6, wherein forming the contact opening includes:
removing the patterning layer after forming the sacrificial plug;
depositing a dielectric layer encapsulating the bit lines, the sacrificial plug, and the conformal layer; and
exposing the sacrificial plug based on removing and planarizing the dielectric layer, wherein the sacrificial plug is exposed for subsequent etching process that forms the contact opening.

8. The method of claim 6, wherein forming the sacrificial plug includes depositing a material having a removal characteristic different than the conformal layer, the patterning layer, the cover layer, or a combination thereof.

9. The method of claim 8, wherein the material for the sacrificial plug includes a metallic material having a processing temperature lower than 90ºC.

10. The method of claim 1, wherein the semiconductor device comprises a semiconductor wafer including a memory array having the data storage cells, wherein the memory array further includes the bit lines.

11. The method of claim 10, wherein the semiconductor wafer is a second semiconductor wafer, the method further comprising:
bonding a first semiconductor wafer over the second semiconductor wafer, wherein the first semiconductor wafer is connected to the landing pad for electrically coupling to the target bit line.

12. The method of claim 11, wherein the first semiconductor wafer includes a control circuit that is coupled to the target bit line and configured to access the target bit line through the self-aligned vertical connector.

13. The method of claim 12, wherein the first and second semiconductor wafers comprise a Flash memory device.

14. An apparatus, comprising:
a functional circuit;
a vertical connector over the functional circuit, the vertical connector having (1) a lower portion with a first width and (2) an upper portion with a second width greater than the first width,
wherein the upper and lower portions are concentrically aligned, and
wherein the vertical connector is configured to provide an electrical connection to the functional circuit along a vertical direction.

15. The apparatus of claim 14, wherein:
the apparatus comprises a memory device; and
the functional circuit includes:
a set of memory cells, and
a target bit line over and electrically coupled to the set of memory cells, wherein the target bit line is below and directly connected to the lower portion of the vertical connector.

16. The apparatus of claim 15, wherein:
the vertical connector is located at a corresponding target location;
the set of memory cells comprise a memory array; and
the functional circuit having:
a set of bit lines that extend parallel to each other and along a lateral direction, wherein the set of bit lines includes the target bit line,
separation spaces extending along the lateral direction and below the set of bit lines, wherein each separation space is between and separates adjacent pair of bit lines, and
a conformal material (1) contacting opposing sides of the target bit line at the target location and (2) surrounding peripheral edges of the vertical connector, wherein the conformal material fills portions of separation spaces adjacent to the target bit line at the target location.

17. The apparatus of claim 16, wherein the functional circuit includes a dielectric layer contacting and surrounding peripheral portions of the conformal material, the dielectric layer (1) encompassing the set of bit lines outside of the target location and (2) encompassing and defining gaps in the separation spaces outside of the target location.

18. The apparatus of claim 16, wherein:
the functional circuit and the vertical connector comprise a second wafer; and
the apparatus comprises a Flash memory that further includes a first wafer over and bonded to the second wafer, the first wafer including control circuit electrically coupled to the memory array through the vertical connector.

19. The apparatus of claim 15, wherein:
the functional circuit having a set of bit lines that extend parallel to each other and along a lateral direction, wherein the set of bit lines includes the target bit line; and
the vertical connector comprises a set of connectors that each connect to a unique bit line in the set of bit lines, wherein connectors in the set of connectors have concentrically arranged upper and lower portions.

20. The apparatus of claim 14, wherein the vertical connector includes uniform material that is integral along a vertical direction across the lower portion and the upper portion according to a characteristic of a single metallization process used to form the vertical connector.
